(19) United States
(12) Patent Application Publication
(10) Pub. No.: US 2020/0122378 A1
(43) Pub. Date: Apr. 23, 2020

(54) MULTILAYERED ANISOTROPIC MICROPARTICLES

(71) Applicant: CASE WESTERN RESERVE UNIVERSITY, Cleveland, OH (US)

(72) Inventors: Al de LEON, Cleveland, OH (US); Rigoberto C Advincula, Cleveland, OH (US); Eric Baer, Cleveland, OH (US)

(21) Appl. No.: 16/474,258

(22) PCT Filed: Dec. 27, 2017
(86) PCT No.: PCT/US2017/068533

§ 371 Date: Jun. 27, 2019

Related U.S. Application Data
(60) Provisional application No. 62/439,293, filed on Dec. 27, 2016.

(51) Int. Cl. B29C 48/00; B29C 48/18; C23C 14/04; C23C 14/20; C23C 14/34; C23C 14/58

(52) U.S. Cl. CPC B29C 48/0022; B29C 48/18; C23C 14/042; B29L 2009/003; C23C 14/34; C23C 14/5873; B29C 2793/009; C23C 14/20

(57) ABSTRACT

A method of forming multilayer polymer composite particles includes coextruding a multilayer polymer composite sheet having alternating first and second polymer layers. The multilayer polymer composite sheet is divided into a plurality of anisotropic multilayer polymer composite microparticles.

### RELATED APPLICATIONS

This application claims the benefit of U.S. provisional application No. 62/439,293, filed Dec. 27, 2016, the entirety of which is incorporated by reference herein.

### GOVERNMENT FUNDING

This invention was made with government support under Grant No. DMR-0423914 awarded by The National Science Foundation. The United States government has certain rights to the invention.

### BACKGROUND

Expanding single-component microparticles into anisotropic particles with discrete domains of different functionalities has been shown to widen the application of colloidal particles in biomedical, self-assembly, and electronics application. Imbuing several functionalities to a particle requires the particle itself to have anisotropic architecture. The main benefit of utilizing anisotropic particles is the ability to individually tune the dimension, chemical composition, and functions of each domain. The use of anisotropic particles offers more functionality and higher efficiency as compared to using a mixture of isotropic particles.

Anisotropy in particles could be in terms of shape, surface chemistry or chemical composition. There are a number of ways to fabricate particles with shape anisotropy (also known as asymmetric particles). More popular methods include micromolding, stretching, and using microfluidic channels.

It has been shown that nonspherical particles can be fabricated by first embedding polymeric particles into a polyvinyl alcohol matrix. The particle-loaded matrix is then heated above the glass transition temperature of the particle and then mechanically stretched. Consequently, the loaded particle, which is deformable above its glass transition temperature, is forced to follow the reformed matrix. The asymmetric particles are released upon cooling and dissolution of the matrix.

Shape anisotropic particles can also be successfully prepared by micromolding. Polymerizable monomers can be loaded into the cavities with definite shapes of a perfluoropolyether elastomeric mold. The monomer is subsequently polymerized by exposing it to ultraviolet light. Upon polymerization, the particles can be harvested by transferring them into a glass substrate coated with a cyanoacrylate, which is then polymerized with moisture. Dissolution of the polycyanoacrylate releases the particles of definite shapes.

Another approach is to form anisotropic particles by utilizing microfluidic technology. For example, droplets of a UV-curable polymer can be formed at a T-junction by shearing the dispersed polymer phase with a continuously flowing aqueous phase. The shapes of the droplet are precisely controlled by confining it in a microchannel of different geometries. The designed shape is fixed by curing the polymer droplet using ultraviolet light. With this approach, plug- and disk-like particles can be fabricated.

Chemically anisotropic particles with at least two discrete phases of different chemical composition have been the focus of many researchers because of their application on drug delivery and imaging. The preparation of chemically anisotropic particles can be done by self-assembly, masking process, and using microfluidic technology. Cross-linked anisotropic particles have been made by self-assembling terpolymers including polystyrene (PS), polybutadiene (PB), and poly(methyl methacrylate) (PMMA). On the other hand, masking involves exposing just one part of the particle to a reactive environment while the other part is left protected. In one example, partially coated latex spheres with gold are formed before chemically modifying the gold with an ionizable group. The resulting particles have pH-dependent electric dipole moments. Particles with at least two distinct phases can also be prepared by letting a number of immiscible monomers form a droplet by emulsification in an aqueous solution with surfactant. With this technique, incorporating up to three different materials into one particle has been demonstrated.

### SUMMARY

This application relates to a multilayered polymer composite microparticle having anisotropic properties. The application provides a method of fabricating anisotropic multilayer microparticles by combining forced assembly by layer-multiplying coextrusion with various dividing processes, e.g., mechanical, chemical, etching, to form multilayered microparticles having anisotropic properties. In one example, reactive ion etching is used to form the microparticles. The etching parameters can be optimized to achieve high-throughput, anisotropic etching of multilayered polymer films with vertical sidewall profiles. The method utilizes the shadow masking technique that improves the flexibility in designing the final shape of the fabricated microparticle. To this end, multilayered microparticles with different shapes and aspect ratios were fabricated.

Although the application describes one example dividing process being reactive ion etching to form the anisotropic microparticles, it will be appreciated that alternative etching techniques could be utilized, as well as mechanical, chemical or other processes. In any case, anisotropic microparticles can be formed having dimensions on the micro- or nano-level. For example, the anisotropic particles can have dimensions on the order of about 100 μm, on the order of about 50 μm, on the order of about 10 μm or on the order of about 500 nm.

### BRIEF DESCRIPTION OF THE DRAWINGS

FIGS. 1A-1G illustrate steps for fabricating anisotropic multilayer microparticles from a multilayered, polymer composite sheet.

FIGS. 2A-2B illustrate an alternative process for forming anisotropic multilayer microparticles.

FIGS. 3A-3F illustrate reactive ion etching the anisotropic multilayer microparticles under different operating conditions.

FIGS. 3A-3B illustrate an array of multilayered microparticles having different sizes.

FIG. 3C shows released anisotropic multilayer microparticles after removal of a gold mask.

FIG. 3D shows a surface of the silicon substrate after the anisotropic multilayer microparticles were released therefrom.

FIG. 4A illustrates a FT-IR spectrum of an array of anisotropic multilayer microparticles.

FIG. 4B illustrates a FT-IR Image (absorbance) of an array of anisotropic multilayer microparticles.

FIGS. 5A-5D illustrate anisotropic multilayer microparticles having different shapes.

### DETAILED DESCRIPTION

Although there are a number of existing technologies for fabricating shape and chemically anisotropic microparticles, no technique so far can effectively fabricate multilayered (e.g., more than three layers) microparticles of definite shapes. This application described a method for fabricating multilayered microparticles with shape and/or chemical anisotropy by combining forced assembly by layer-multiplying coextrusion to produce multilayered polymer composite films with dividing processing for forming the multilayered film into microparticles having anisotropic properties. Example dividing processes can include mechanical, chemical, and etching processes.

Forced assembly by layer-multiplying coextrusion is a process in which layers made from at least two different polymers are formed by melting and extruding through a series of layer multipliers. The strength of the process lies in fabricating polymer films having hundreds or thousands of layers. In addition, the thickness of each layer can be set in micro- or nanoscale depending on the application. This technology has been successfully utilized in fabricating one-dimensional photonic crystals, photo-patternable reflective films, packaging films with excellent oxygen barrier property, and multilayered gradient-index lenses.

In one example, the process used to divide the multilayer film into anisotropic microparticles includes reactive ion etching (REI). RIE utilizes chemically reactive plasma generated under low pressure by an electromagnetic field to attack and react with the target material. It has been used to control the surface morphology and wettability of polymers to improve their compatibility with biological systems. It has also been utilized to reduce the size of polymeric microparticles arranged in an array, and to fabricate nanofibrillar surfaces and complex 2D and 3D arrays of nonspherical colloidal microparticles of various shapes. Moreover, it has been demonstrated that controlling the chemistry of the reactive ions allows the etching to be performed anisotropically. That is, the etching process proceeds only along the line of sight of the reactive ions and, thus, lateral etching is minimized (if not completely prevented).

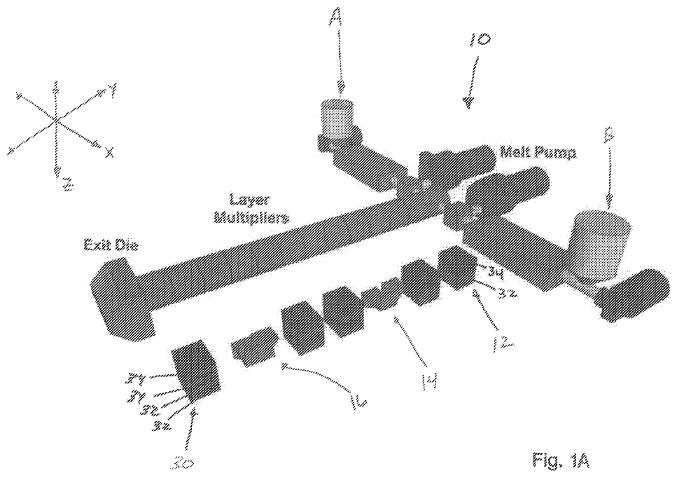

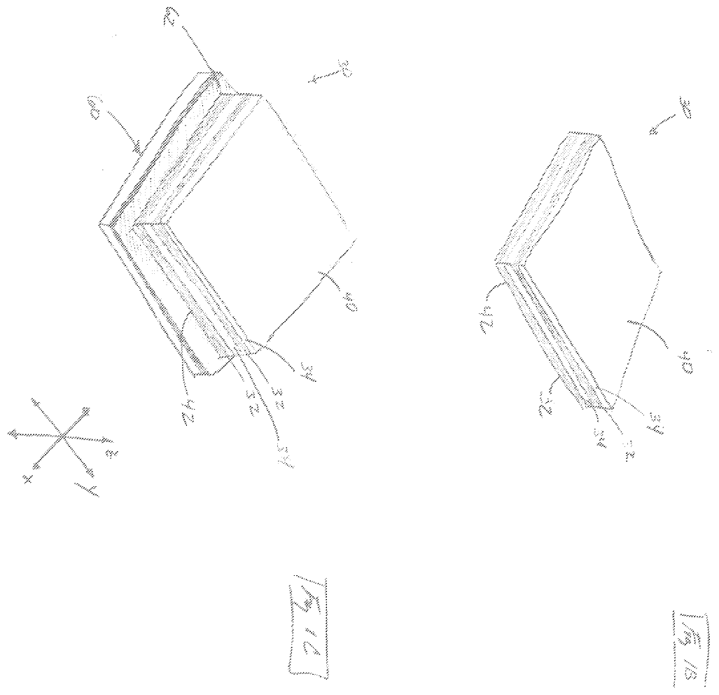

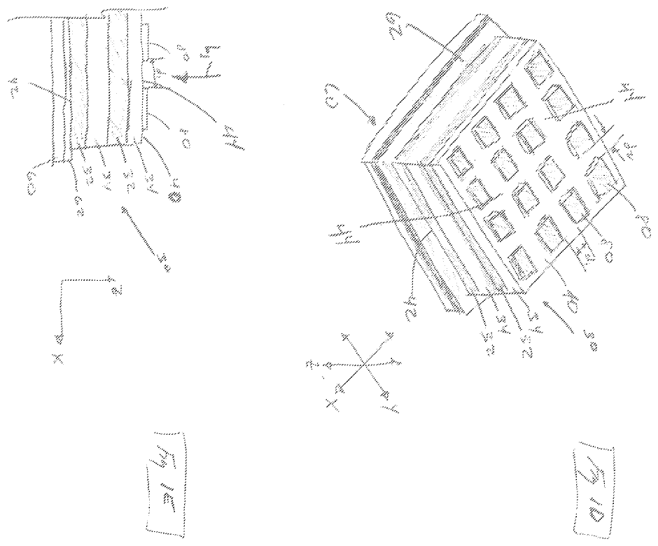

FIG. 1A illustrate an example coextrusion and multiplying or multilayering process 10 used to form a multilayered polymer composite film or sheet 30. In the process 10, a first polymer layer 32 and a second polymer layer 34 are provided. The first layer 32 is formed from a first polymer material (A) and the second polymer layer 34 is formed from a second polymer material (B) that has a substantially similar viscosity and is substantially immiscible with the first polymer material (A) when coextruded.

The first and second polymer materials (A), (B) are coextruded to form a polymer composite having a plurality of discrete layers 32, 34 that collectively define a multilayered polymer composite stream 12. It will be appreciated that one or more additional layers formed from the polymer materials (A) or (B) or formed from different polymer materials may be provided to produce a multilayered polymer composite stream 12 that has at least three, four, five, six, or more layers of different polymer materials. Although one of each layer 32 and 34 is illustrated in the composite stream 12 of FIG. 1A it will be appreciated that the composite stream 12 may include, for example, up to thousands of each layer 32, 34. In any case, the multilayered polymer composite stream 12 is then divided, stacked, and multiplied to form the multilayered polymer composite film 30 having, for example, hundreds or thousands of layers 32, 34.

To this end, a pair of dies 14, 16 is used to multiply the coextruded layers 32, 34. Each layer 32, 34 initially extends in the y-direction of an x-y-z coordinate system. The y-direction defines the length of the layers 32, 34 and extends in the general direction of flow of material through the dies 14, 16. The x-direction extends transverse, e.g., perpendicular, to the y-direction and defines the width of the layers 32, 34. The z-direction extends transverse, e.g., perpendicular, to both the x-direction and the y-direction and defines the height or thickness of the layers 32, 34. The dies 14, 16 cooperate to form multilayered polymer composite film 30 having a first surface 40 and an opposing second surface 42 spaced along z-axis.

Polymer materials used in the process described herein can include a material having a weight average molecular weight (MW) of at least 5,000. Preferably, the polymer is an organic polymeric material. Such polymer materials can be glassy, crystalline or elastomeric polymer materials.

Examples of polymer materials that can potentially be coextruded to form the first and second polymer materials (A), (B) include, but are not limited to, polyesters, such as poly(ethylene terephthalate) (PET), poly(butylene terephthalate), polycaprolactone (PCL), and poly(ethylene naphthalate)polyethylene; naphthalate and isomers thereof, such as 2,6-, 1,4-, 1,5-, 2,7-, and 2,3-polyethylene naphthalate; polyalkylene terephthalates, such as polyethylene terephthalate, polybutylene terephthalate, and poly-1,4-cyclohexanedimethylene terephthalate; polyimides, such as polyacrylic imides; polyetherimides; styrenic polymers, such as polystyrene (PS), atactic, isotactic and syndiotactic polystyrene, α-methyl-polystyrene, para-methyl-polystyrene; polycarbonates, such as bisphenol-A-polycarbonate (PC); polyethylenes oxides; poly(meth)acrylates such as poly(isobutyl methacrylate), poly(propyl methacrylate), poly(ethyl methacrylate), poly(methyl methacrylate), poly(butyl acrylate) and poly(methyl acrylate) (the term “(meth)acrylate” is used herein to denote acrylate or methacrylate); cellulose derivatives; such as ethyl cellulose, cellulose acetate, cellulose propionate, cellulose acetate butyrate, and cellulose nitrate; polyalkylene polymers such as polypropylene, polyethylene, high density polyethyelene (HDPE), low density polyethylene (LDPE), polybutylene, polyisobutylene, and poly(4-methyl)pentene; fluorinated polymers such as perfluoroalkoxy resins, polytetrafluoroethylene, fluorinated ethylene-propylene copolymers, polyvinylidene fluoride, polyvinylidene difluoride (PVDF), and polychlorotrifluoroethylene and copolymers thereof; chlorinated polymers such as polydichlorostyrene, polyvinylidene chloride and polyvinylchloride; polysulfones; polyethersulfones; polyacrylonitrile; polyamides such as nylon, nylon 6,6, polycaprolactam, and polyamide 6 (PA6); polyvinylacetate; polyether-amides.

Copolymers, such as styrene-acrylonitrile copolymer (SAN), preferably containing between 10 and 50 wt %, preferably between 20 and 40 wt %, acrylonitrile, styrene-ethylene copolymer; and poly(ethylene-1,4-cyclohex-ylenedimethylene terephthalate) (PETG), can also be used as either polymer material (A), (B). Additional polymer materials include an acrylic rubber; isoprene (IR); isobutylene-isoprene (IIR); butadiene rubber (BR); butadiene-styrene-vinyl pyridine (PSBR); butyl rubber; chloroprene (CR); epichlorohydrin rubber; ethylene-propylene (EPM); ethylene-propylene-diene (EPDM); nitrile-butadiene (NBR); polyisoprene; silicon rubber; styrene-butadiene (SBR); and urethane rubber. Polymer materials can also include include block or graft copolymers. In one instance, the polymer materials used to form the layers 32, 34 may constitute substantially immiscible thermoplastics that when coextruded have a substantially similar viscosity.

In addition, each individual layer 32, 34 may include blends of two or more of the above-described polymers or copolymers. The components of the blend can be substantially miscible with one another yet still maintaining substantial immiscibility between the layers 32, 34.

In some embodiments, the polymer materials comprising the layers 32, 34 can include organic or inorganic materials, including nanoparticulate materials, designed, for example, to modify the mechanical properties of the polymer materials, e.g., tensile strength, toughness, and yield strength. It will be appreciated that potentially any extrudable polymer material can be used as the first polymer material (A) and the second polymer material (B) so long as upon coextrusion such polymer materials (A), (B) are substantially immiscible, have a substantially similar viscosity, and form discrete layers or polymer regions. In one example, the first polymer material (A) constitutes polystyrene and the second polymer material (B) constitutes PMMA.

FIGS. 1C-1G depict one example manner in which anisotropic multilayer microparticles are formed by dividing the multilayered polymer composite film 30. In this example, the anisotropic multilayer microparticles are formed by etching the multilayered polymer composite film 30. Referring to FIG. 1C, a substrate layer 60 is secured to the second surface 42 of the multilayered polymer composite film 30 with an adhesive 62, e.g., poly(vinyl alcohol) (PVOH). The substrate 60 acts as a support structure for the multilayered polymer composite film 30 and extends within the x-y plane.

As shown in FIG. 1D, after the substrate layer 60 is secured to the second surface 42, a metal 80 is deposited onto the first surface 40 through a patterned shadowmask (not shown). The metal 80 is selected to be resistant to or inhibit etching. In one example, the metal deposits 80 are gold. In any case, the metal deposits 80 are arranged in a predetermined pattern on the first surface 40. In one example, a 4×4 array or grid of metal deposits 80—each having a rectangular cross-section—is symmetrically deposited onto the first surface 40. It will be appreciated, however, that the array could be asymmetric, any of the individual metal deposits 80 could have a different polygonal cross-section (square, rectangular, hexagonal, star-shaped, diamond, etc.) or round cross-section (circular, elliptical, etc.) and/or the metal deposits could have different shapes from one another.

In any case, portions 44 of the top surface 40 are exposed between the metal deposits 80. These portions 44 are removed by etching, e.g., via REI, in order to form anisotropic, multilayer polymer composite microparticles 100 (see FIG. 1G). More specifically, an etching gas is directed downwards in the direction L₁ (FIG. 1E) onto the exposed portions 44. The etching gas removes the exposed portions 44 of the multilayer polymer composite film 30 between the metal deposits 80 all the way down to the adhesive layer 62 or substrate 60 (see FIG. 1F). The portions of the multilayer polymer composite film 30 aligned with the metal deposits 80 in the z-direction are undisturbed by the etching process and remain as multilayer polymer composite microparticles 100 having anisotropic properties.

Fabricating anisotropic multilayer microparticles 100 via RIE can be optimized by controlling the surface profile of the sidewall 102 of the final microparticle 100. Desirable anisotropic etching depends on very little or no reaction at the sidewall 102, or that the deposition and etching rates should be balanced exactly. During the RIE process, oxygen gas dissociates into oxygen radicals, which then reacts with the multilayered polymer composite film 30 to produce CO, CO₂, and H₂O. Increasing the flow rate of oxygen increases the number of radicals, thereby increasing the etch rate. Increasing the O₂ flow rate, however, makes the sidewall 102 surface rougher and lateral attack of the sidewall by the O₂ becomes extensive. That said, it is desirable to adjust the RIE gas chemistry to have a high throughput, anisotropic etching of the multilayer polymer composite film 30.

There are two approaches to obtain a vertical sidewall 102 profile in RIE for the microparticles 100. One is to dilute the etching gas (O₂) with an inert gas like Ar or N₂. Such mixture has been used to anisotropically etch poly(arylene ether). Nevertheless, diluting the etchant causes the etch rate to decrease significantly. Another approach is to mix the etching gas with a passivating gas like BCl₃, CF₄, CHF₃, etc. The anisotropic etching in this case is brought about by the production of halogenated radicals, e.g., CF₄ produces fluorine radicals. These fluorine-based radicals react with the sidewall 102 and form a passivation layer (not shown) that limits sideways etching of the multilayered polymer composite film 30 and reduces undercutting of the mask 80. Increasing the flow rate of CF₄ increases the degree of anisotropy but drastically decreases the etch rate.

It is noteworthy that anisotropic etching of the multilayered polymer composite film 30 using pure oxygen can be performed if the temperature is reduced to around −60° C. It has been suggested that this is brought about by the condensation of water on the sidewall 102, which acts as the passivating layer. In this case, the ratio of O₂ and CF₄ will be fixed to 1:1 to have a reasonably fast etch rate and smooth sidewalls 102 with vertical profiles will be formed.

In any case, due to this process, each of the sidewalls 102 of the microparticles 100 can extend parallel to one another and have reduced surface finish due to the reduced interaction between the incoming etching gas and the sidewall. Referring to FIG. 1F, the distances d₁, d₂ between metal deposits 80 in the x and y directions, respectively, impact the size and shape of the resulting microparticles 100 shown in FIG. 1G. That said, the distances d₁, d₂ help to determine how many microparticles 100 are formed from the multilayered polymer composite film 30 and the size thereof. It will be appreciated that particles 100 can be formed having dimensions on the micro- or nano-level. For example, the particles 100 can have dimensions on the order of about 100 μm, on the order of about 50 μm, on the order of about 10 μm or on the order of about 500 nm.

Once the etching is performed, the adhesive layer 62 is removed by dissolving to separate the microparticles 100 from the substrate 60. The metal deposit 80 can remain on the microparticles 100 (as shown) or be removed from the microparticles (not shown) by dissolving.

In another example, the process used to divide the multilayer film includes mechanical chopping and/or cutting. Referring to FIGS. 2A-2B, the microparticles 100 are mechanically formed from the multilayer polymer composite film 30. More specifically, the multilayered polymer composite film 30 is provided in a rolled form and fed in the manner L₂ to a machine 110 that includes a stationary blade 112 and blade 114 that rotates in the manner R. The blades 112, 114 cooperate to cut or chop the multilayer polymer composite film 30 into the anisotropic microparticles 100. The circumferential spacing between the cutting tines 116 on the blade 114 help to determine the dimensions of the microparticles 100. Microparticles 100 formed by this mechanical operation have dimensions in each direction on the order of about 50 μm.

The fabricated anisotropic multilayer microparticles described herein have a defined shape are believed to have the following advantages over isotropic microparticles: (1) the ability to simultaneously utilize the different functions incorporated into the microparticle, (2) various components can be incorporated into different domains, even those that are normally incompatible with each other, and (3) by controlling the shape one can control the microparticles flow behavior.

The anisotropic microparticles of the described herein can be used in a variety of applications due to their ability to be specifically tailored layer-by-layer to meet the particular design criterion. To this end, each layer in the anisotropic microparticle can be loaded with one or more different molecules. The anisotropic microparticles can, for example, be used in pharmaceutical applications (such as drug delivery or other controlled release technologies); catalysis applications; agricultural applications (such as fertilizer and pesticides); security, labeling, and packing applications; optical devices; military applications (such as infrared and ultraviolet labeling); dye, ink, and printing applications; and painting applications. To this end, each layer 32, 34 in the anisotropic multilayer microparticle 100 can be infused with drugs, dies, etc.

### Example

### Experimental Section

### Layer-Multiplying Coextrusion

In this example, polystyrene (PS) (Styron 615 APR, The Dow Chemical Company) and poly(methyl methacrylate) (PMMA) (Plexiglas VM-100, Arkema Inc.) were separately melted at 225° C. and 235° C., respectively. Both polymer melts have the same viscosity at these temperatures. The volumetric flow rates of both PS and PMMA were set at 3.0 cm³ min⁻¹. The melted polymers were combined in such a way that one is on top of the other. The combined polymer melt flowed through five multiplier dies to achieve the desired number of layers. The multiplying elements and the surface layer feed block were maintained at 230° C.

The multilayered melt then passed through the exit die as a multilayer polymer composite film having 32 coextruded bilayers of PS and PMMA. The exit die was maintained at 220° C. The temperature of the chill roll was maintained at 57.2° C. The extruded film had a thickness of 28 μm [in the z-direction] measured using a micrometer.

### Sputtering and Reactive Ion Etching

The multilayered film was adhered to a silicon wafer substrate pre-coated with poly(vinyl alcohol) (PVOH). The PVOH acted as the adhesive and the sacrificial layer for the release later. A very thin (about 100 nm thick) layer of gold was deposited/sputtered through a shadow mask onto the top surface of the multilayered film. These gold deposit portions were to remain intact during the etching process. Subsequently, the exposed portions of the multilayered film between the gold deposits was then etched away with reactive ions of O₂ and CF₄ for 1 hour. The RF power was set at 20 W, 60 W, and 100 W for the optimization run. Different flow rates of O₂ and CF₄ was used for the optimization. The sacrificial PVOH layer and the gold deposit mask were then dissolved by dropping aqueous gold etchant. This produced independent, multilayered polymer composite microparticles having anisotropic properties.

### Instrumentation

SEM analysis was done using JEOL JSM-6510LV SEM. FT-IR Imaging was conducted on Digilab FTS 7000 spectrometer, a UMA 600 microscope, and a 32×32 MCT IR Imaging focal plane array (MCT-FPA) image detector with an average spatial area of 176×176 μm in the reflectance mode.

### Results and Discussions

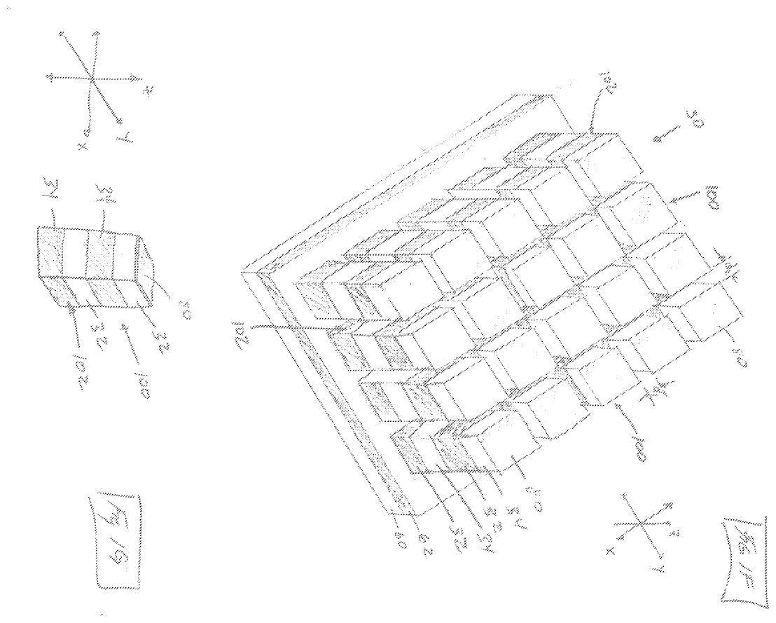

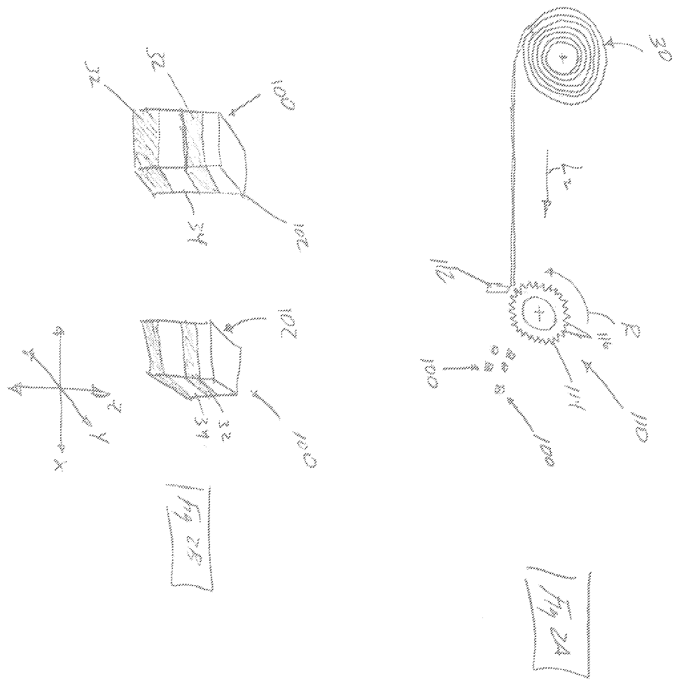

FIGS. 3A-3F show the effect on the anisotropic microparticles of changing the RF power and the gas flow rate on the etching process. The pressure was kept as low as possible in each etching process to increase the mean free path of the ions, which has been shown to enhance the ion bombardment effect. At the very low RF power of 20 W, the etching rate was very slow—etching about 2 μm in 1 hr (FIG. 3A). Grass-like residues were present at the bottom surface between microparticles. This could be caused by the micromasking effect caused by redeposition of the metal mask or the silicon substrate material during the etching process.

Increasing the power to 60 W (FIG. 3B) etched the exposed multilayer polymer film at a reasonable rate while maintaining a high degree of anisotropy. Increasing the etching power further to 100 W (FIG. 3C) caused the sidewall of each microparticle to be very rough, thereby making it difficult to differentiate individual layers in the microparticle.

Similarly, the etching gas flow rate dictates the rate and how rough the resulting microparticle sidewall becomes. At very low gas flow rate, even after etching for 1 hour the multilayer polymer film was barely etched away (see FIG. 3d). Increasing the flow rate to 25 sccm etched the multilayer polymer film all the way to the silicon substrate and produced very smooth microparticle sidewalls (FIG. 3E).

Increasing the etching gas flow rate further caused a very fast etching rate but produced a very rough sidewall. (FIG. 3F) The increase in etching gas flow rate causes the pressure inside the RIE apparatus to increase. This increase in pressure correlated with having rough microparticle sidewalls and increased amount of residue at the bottom of the microparticles. The etching gas flow rates were also kept low (maximum is 200 sccm total) to avoid disturbing the formed microparticles and releasing them even before dissolving the sacrificial substrate layer.

Plasma containing CF₄ etched PMMA at a faster rate than it etches PS, while O₂ plasma etched PS at a faster rate than it etches PMMA. Mixing O₂ and CF₄ in equal proportion ensured that both polymers were etched away. Although there is still slight preference on one of the polymers, the surface profile of the fabricated multilayered microparticles is vertical (along the z-direction). It is believed that further optimization of the RIE parameters will enable fabrication of perfectly vertical sidewall profile.

An etching gas mixture of O₂ and CF₄ was previously used to etch layered colloidal microparticles to produce layered colloidal crystal structures with different crystal structures and shapes. It has been hypothesized that the plasma generated from the mixture of O₂ and CF₄ contains oxyfluoride ions, which are very reactive to the carbon-carbon bonds in the polymeric backbone. The generated reactive plasma etches the polymer and at the same time protect the sidewall by forming a passivating layer.

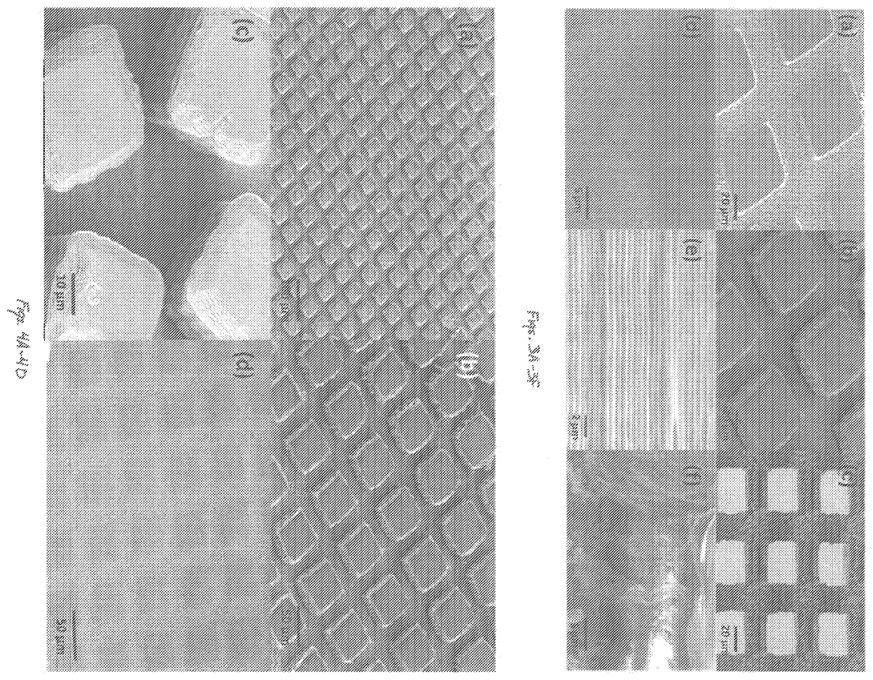

Two arrays of different aspect ratios of anisotropic multilayer microparticles were fabricated by using shadow masks with different opening sizes. The etching parameters were optimized (RF power of 60 W and 25 sccm of O₂ and 25 sccm of CF₄). FIG. 4A shows the SEM image of an array of 30 μm×30 μm×20 μm anisotropic microparticles still secured to the substrate. FIG. 4B shows the SEM image of an array of 50 μm×50 μm×20 μm anisotropic microparticles still secured to the substrate. The exposed surface of the substrate between the microparticles was observed to be smooth with no grassy areas. This is similar to what has been observed before, with the phenomenon being associated with the effective removal of the micromask due to the large ion bombardment effect.

It is noteworthy that the removal of the metal deposit on the anisotropic microparticle is optional and may depend on the application. The presence of the metal deposit provides another level of anisotropy. Interestingly, polymer microparticles with metallic or semiconducting nanoparticle coatings have been demonstrated to have enhanced optical property, i.e., optical nonlinearity or photoluminescence, when arranged in a periodic manner on the scale of the optical wavelength. Polymer-metal biphasic microparticles were also fabricated and demonstrated to have self-propulsion capability.

FIG. 4C shows the released microparticles after the dissolution of the gold mask and the PVOH sacrificial layer. It can be seen that to some extent the part of the polymer film directly underneath the gold metal mask was tapered. This was caused by very high concentration of O₂ and CF₄ radicals at the start of the etching process. As the etching process continued, the gold metal mask collapsed and covered the partially-etched part of the polymer. PVOH was specifically chosen as the sacrificial layer because it has high affinity on piranha-cleaned silicon wafer, and it can act as an effective adhesive to the polymer film.

The PVOH layer can also be dissolved by water, which cannot dissolve both the PS and PMMA. The adhesion is strong enough to keep the microparticles in place during the sputtering of gold and reactive ion etching. FIG. 4D shows that the silicon wafer substrate was partially etched—confirming that the etching process went all the way through the polymer film and the sacrificial layer.

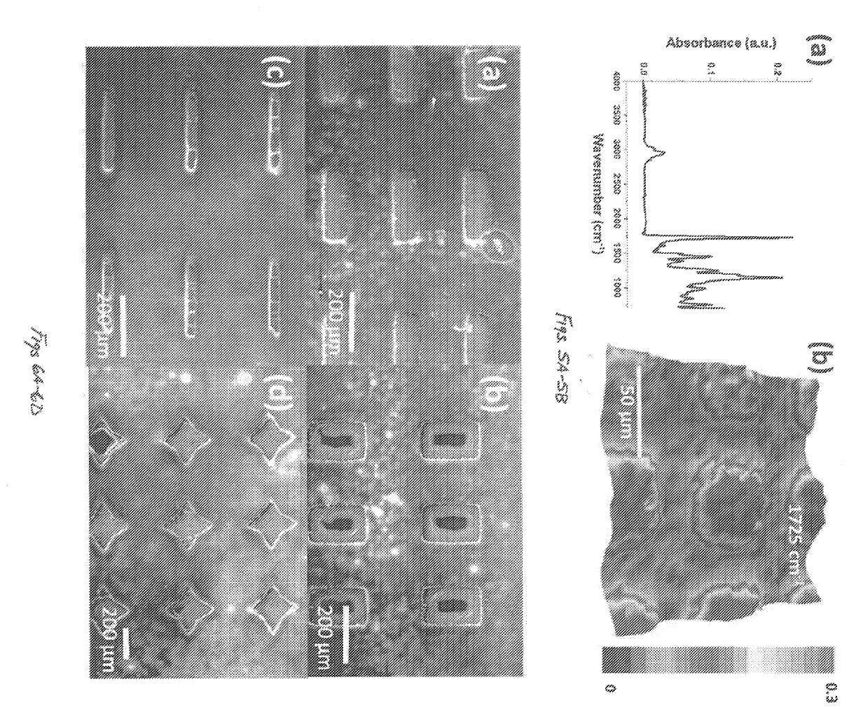

FIG. 5A shows the infrared spectrum of the fabricated multilayered microparticle. The peaks for the PS were assigned as 2800-3000 cm⁻¹ for —C—H₂ stretching vibration of the polymer backbone, 3050 cm⁻¹ for the aromatic—C—H stretching, and 1600 cm⁻¹ and 1500 cm for the aromatic—C═C stretching vibrations. On the other hand, the peaks for the PMMA were assigned as 1735 cm⁻¹ for the C═O stretching, 1450 cm⁻¹ for the (O)CH₃ bending, and 990 cm⁻¹ for the (O)CH₃ rocking coupled with C—O—C stretching. It is evident that the molecular integrity of the multilayered microparticle was preserved during the masking and etching processes.

FIG. 5B shows the FT-IR image of the array of microparticles after the etching process and the removal of the metal mask. FT-IR imaging uses a focal plane array detector to provide not only the spectral image but also the spatial image at a specific wavelength corresponding to a chemical functional group. The technique enables the identification of chemical groups distribution from a corresponding optical image and distinguishes the presence of overlapping species within the same region. It is therefore a very powerful tool for the analysis and evaluation of the success of the etching process.

FIG. 5B indicates that only those portions of the multilayer film that were initially protected by the metal mask were left after the etching process, which was evidenced by the intense absorption at 1725 cm⁻¹ up to 0.3. On the other hand, any regions of the multilayer film that were not protected by the metal mask were completely etched away, which was confirmed by the very low absorbance at those regions.

One of the key advantages of the combined forced assembly by layer-multiplying coextrusion technique and reactive ion etching described herein is the ability to easily tune the shape of the fabricated microparticle. Some of techniques for fabricating microparticles with shape anisotropy—such as micromolding and microfluidics—have been extended to incorporate more than one type of material or layer in the asymmetric microparticle. However, fabricating asymmetric microparticles having more than three layers using imprint lithography was found to be very challenging.

To demonstrate the flexibility of the present approach, different shadow masks with various shapes was used. Rectangular multilayered microparticles of various sizes and aspect ratios (200 μm×50 μm×20 μm, 200 μm×100 μm×20 μm, and 200 μm×20 μm×20 μm) were shown in FIGS. 6A-C. These microparticles were fabricated without changing the RIE parameter setting. Star-shape microparticles about 300 μm wide were also fabricated.

### CONCLUSION

It has been demonstrated that the combined forced assembly by layer-multiplying coextrusion technique and reactive ion etching enables the possibility of fabricating anisotropic multilayer microparticles. High-throughput anisotropic etching of multilayered film can be realized by carefully optimizing the reactive ion etching parameters such as the gas flow rate, gas chemistry, and the RF power. Lastly, the flexibility of the presented technique was demonstrated by fabricating microparticles of different shapes and aspect ratios. It is believed that this technology will open a lot of options for improving the existing application of anisotropic microparticles.

From the above description, those skilled in the art will perceive improvements, changes and modifications. Such improvements, changes and modifications within the skill of the art are intended to be covered by the appended claims. All references, publications, and patents cited in the present application are herein incorporated by reference in their entirety.

1. A method of forming multilayer polymer composite particles comprising:
coextruding a multilayer polymer composite sheet comprising alternating first and second polymer layers; and
dividing the multilayer polymer composite sheet into a plurality of multilayer polymer composite microparticles having anisotropic properties.

2. The method of claim 1, the step of dividing the multilayer polymer composite sheet comprising mechanically separating the multilayer polymer composite sheet into anisotropic multilayer microparticles.

3. The method of claim 2, the step of dividing the multilayer polymer composite sheet comprising cutting the multilayer polymer composite sheet with a rotating blade and a stationary blade.

4. The method of claim 1, the step of dividing the multilayer polymer composite sheet comprising etching the multilayer polymer composite sheet into the anisotropic multilayer microparticles.

5. The method of claim 4, the etching being reactive ion etching.

6. The method of claim 4 further comprising:
securing a base polymer layer to a first surface of the multilayer sheet;
depositing a metal layer onto a second surface of the multilayer sheet in a discrete pattern such that portions of the multilayer sheet are exposed through the metal layer;
etching the exposed portions of the multilayer sheet; and
removing the base polymer layer to form the anisotropic multilayer microparticles.

7. The method of claim 6 further comprising removing the metal layer to form anisotropic multilayer microparticles.

8. The method of claim 6, the base polymer layer being removed by dissolving.

9. The method of claim 6, the base polymer layer being spin coat PVOH.

10. The method of claim 6, the step of depositing a metal layer comprising sputtering gold through a shadow mask.

11. The method of claim 6, the discrete pattern comprising polygonal deposits of gold.

12. The method of claim 6, the anisotropic particles having at least one sidewall extending substantially perpendicular to the first and second surfaces.

13. The method of claim 12, each sidewall being free of reaction with the etching process.

14. The method of claim 12, further comprising covering the at least one sidewall with a passivating layer.

15-19. (canceled)

20. The method of claim 1, the anisotropic multilayer microparticles being at least one of square, rectangular, rectangular, polygonal, diamond, circular, round, elliptical, and star-shaped.

21. The method of claim 1, the anisotropic multilayer microparticles having a length of about 30 μm to about 200 μm, a width of about 30 μm to about 100 μm, and a height of about 20 μm.

22. The method of claim 1, the anisotropic multilayer particles being at least one of chemically and mechanically anisotropic.

23. The method of claim 1, the first polymer layer being PS and the second polymer layer being PMMA.

24. The method of claim 1, the anisotropic multilayer microparticles having all dimensions on one of the micro-scale and nano-scale.

25-26. (canceled)

27. A method of forming multilayer polymer composite particles comprising:
providing a multilayer polymer composite sheet having opposing first and second surfaces and comprising coextruded alternating first and second polymer layers;
securing a base polymer layer to the first surface of the multilayer sheet;
depositing a metal layer onto the second surface of the multilayer sheet in a discrete pattern such that portions of the multilayer sheet are exposed through the metal layer;
etching the exposed portions of the multilayer sheet;
removing the base polymer layer to form multilayer polymer composite microparticles having anisotropic properties.

28. (canceled)
